(19) United States
(12) Patent Application Publication
(10) Pub. No.: US 2019/0363727 A1
(43) Pub. Date: Nov. 28, 2019

(54) ANALOG-TO-DIGITAL CONVERTER AND ELECTRONIC DEVICE COMPRISING THE SAME

(71) Applicant: TELEDYNE DALSA B.V., Eindhoven (NL)

(72) Inventor: Henk Derks, Waalre (NL)

(21) Appl. No.: 16/461,805

(22) PCT Filed: Feb. 24, 2017
(86) PCT No.: PCT/NL2017/050117

§ 371 Date: May 17, 2019

(51) Int. Cl. H03M 1/46; H03M 1/06

(52) U.S. Cl. CPC H03M 1/468; H03M 1/0626

(57) ABSTRACT

The present invention relates to an analog-to-digital converter and electronic device comprising the same.

According to the invention, the ADC comprises a comparator comprising a first input for receiving an input signal and a second input for receiving a feedback signal, the comparator being configured to output a comparison signal in dependence of a difference between the input signal and the feedback signal. The ADC further comprises a triggered pulse generator configured for outputting a digital pulse signal, the pulse generator being configured to generate a pulse in said digital pulse signal in dependence of a clock signal when the comparison signal exceeds a first threshold. The ADC also comprises a digital-to-analog converter (DAC) for converting the digital pulse signal into an analog signal, and a low-pass filter for filtering the analog signal and for providing the filtered analog signal to the comparator as the feedback signal.

Analog-to-digital converters (ADCs) are known in the art. These devices are used to convert an analog signal or value into a digital signal or value. A known application of ADCs can be found in image sensors, such as optical or X-ray sensors. The sensors typically comprise a matrix of columns and rows of photo-sensitive pixels. Read-out circuitry is used to individually address rows of pixels and to read-out the pixel signals for each of the pixels in a selected row. Typically, the pixel signal is in the form of a pixel voltage that is stored on a storage capacitor in the pixel. This storage capacitor may be realized in the form of a dedicated capacitor or it may be a parasitic capacitance of another component. In these applications, a separate ADC is mostly used for each column of the matrix to convert the analog pixel voltage of a selected pixel into a corresponding digital value.

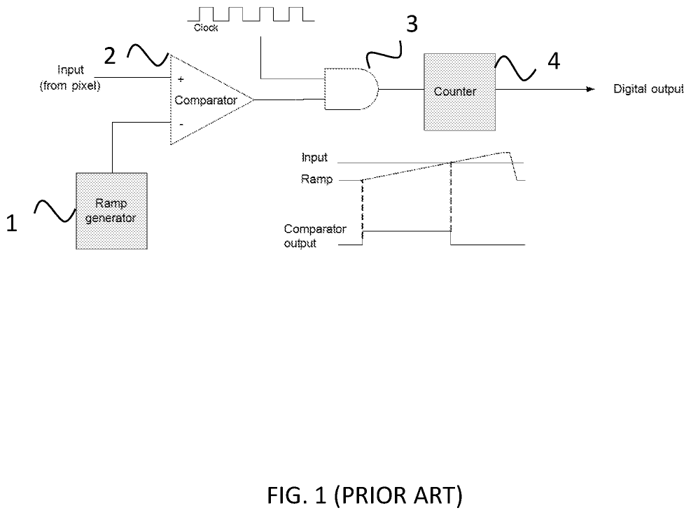

A known ADC arranged in an image sensor is illustrated in FIG. 1. In this example, a ramp waveform is generated by a ramp generator 1 and is globally distributed to all the columns of the image sensor to avoid column to column errors and to reduce power consumption and area. Each column contains a comparator 2 which toggles when the ramp waveform crosses the pixel voltage. The output of comparator 2 is fed to an AND gate 3. The other input of AND gate 3 is configured to receive a clock signal, which is generated by a global clock generator. When the pixel voltage is higher than the ramp waveform, AND gate 3 will output a series of pulses. These pulses are counted by a counter 4. When the pixel voltage is below the ramp voltage, such pulses are not created. This process will end a predetermined amount of time after applying the ramp waveform. At that time, the counter value will be converted into a digital output representing the pixel voltage or the counter value itself is used as an output that represents the pixel voltage. Furthermore, counter 4 will be reset and a new pixel voltage is sampled. A next conversion stage can begin by applying a new ramp waveform and repeating the steps above.

The ADC depicted in FIG. 1 is known as a single slope ADC. Although this design is relatively simple, several disadvantages exist. For example, if the same counter speed is used, the conversion time increases with a factor 2ⁿ, where n is the ADC resolution. Furthermore, it is difficult to achieve a high conversion speed and a high resolution simultaneously. Another disadvantage is related to the noise of the comparator that directly influences the accuracy of the conversion. Additionally, non-linearity of the converter is directly related to the non-linear voltage-charge relationship of the integrating capacitor that is used in ramp generator 1. Hence, a very linear capacitor is required. Another important disadvantage is related to the use of a globally distributed ramp waveform that is prone to cross- talk and may result in comparator kickback of neighboring converters. Any comparator offset will directly relate to the digital output. Moreover, the slope of the ramp waveform needs to be matched to the period of the clock signal if a time-continuous ramp waveform is used.

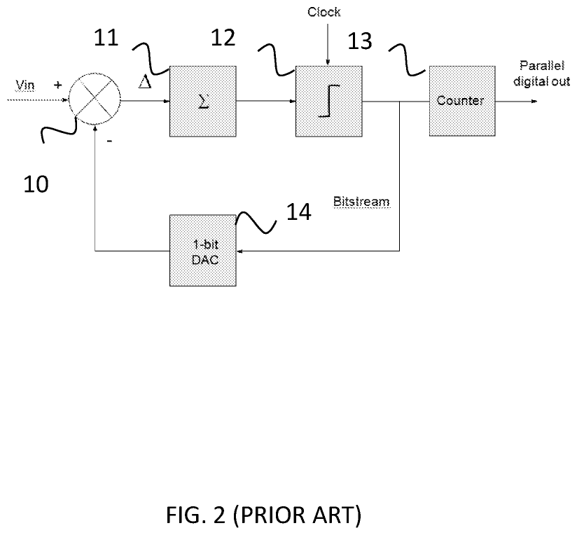

Another known ADC is depicted in FIG. 2. This topology is known as a sigma-delta converter. It comprises a subtractor 10 that subtracts a feedback signal from the inputted signal, e.g. the pixel voltage Vin. This difference signal is fed to an integrator 11. The output thereof is fed to a clocked quantizer/comparator 12 that will output a pulse if the output of integrator 11 exceeds a predefined threshold, e.g. 0V and the clock signal is high. This pulse is counted by a counter 13. In addition, the pulse is fed to a one-bit digital-to-analog converter (DAC) 14, which will produce an analog pulse to subtractor 10.

During operation, when the pixel voltage is relatively low, a pulse generated by DAC 14, will cause a large negative difference that will considerably reduce the output of integrator 11. It will therefore take a longer time for the integrator output to reach a level to cause quantizer/comparator 12 to output a pulse. On the other hand, if the pixel voltage is relatively high, this level will be reached more quickly, and more pulses will be generated per conversion period.

When applying the topology of FIG. 2 in image sensors for converting the pixel voltage, a buffer is required for sampling and holding the pixel voltage as integrator 11 typically requires an input current that would otherwise change the voltage on the storage capacitor of the pixel. Such buffer requires chip area and may be difficult to implement for small pixel pitches. Furthermore, the use of buffers increases the power and current consumption of the sensor.

It is an object of the present invention to provide an ADC in which at least some of the abovementioned problems do not occur or at least at a lesser extent.

This object is achieved with the ADC according to claim 1 which comprises a comparator comprising a first input for receiving an input signal and a second input for receiving a feedback signal, the comparator being configured to output a comparison signal in dependence of a difference between the input signal and the feedback signal. The ADC further comprises a triggered pulse generator configured for outputting a digital pulse signal, the pulse generator being configured to generate a pulse in said digital pulse signal in dependence of a clock signal when the comparison signal exceeds a first threshold. This first threshold may be zero Volts.

The ADC further comprises a digital-to-analog converter (DAC) for converting the digital pulse signal into an analog signal, and a low-pass filter for filtering the analog signal and for providing the filtered analog signal to the comparator as the feedback signal.

Unlike the topology in FIG. 2, a voltage can be inputted to the quantizer/comparator which does not need to be transformed into a current for a subsequent integrator. Typically, a comparator has a high input impedance and will therefore not or hardly affect the pixel voltage. A buffer can therefore be omitted.

The ADC may further comprise an output unit configured for receiving the digital pulse signal and for outputting a digital signal in dependence of the received digital pulse signal. This digital signal may comprise a digital word or digital value representing the magnitude of the input signal. The output unit may comprise a counting unit for counting the number of pulses in the digital pulse signal during a predefined amount of time, and a digital signal generating unit for generating the digital signal in dependence of the counted number of pulses.

The ADC may further comprise a sample-and-hold circuit for sampling a value of a signal to be converted and for providing a signal, which has a value that corresponds to the sampled value, as the input signal to the comparator. When the pixel voltage is sampled and held, the pixel may be reset for a subsequent reading while the last outputted pixel voltage is still being converted.

The ADC may comprise an initialization unit for setting the feedback signal to a predefined level. Setting the feedback signal to a predefined level may increase the speed of the conversion, i.e. reduce the time required after applying the input signal to obtain a reliable output value. Advantageously, the predefined level substantially equals the value of the input signal.

As an example, when using the abovementioned sample-and-hold circuit, the circuit may comprise a sampling unit for sampling the value of the signal to be converted and a holding unit for holding the sampled value during a predefined amount of time, wherein the initialization unit is configured to set the feedback signal to said predefined level at the start of holding the sampled value by the holding unit.

The triggered pulse generator may comprise a gated latch and a logical gate connected to the latch, wherein the logical gate is configured to output the pulse in dependence of an output of the gated latch and the clock signal. For example, the gated latch may comprise a gated D latch having an input port for receiving the comparison signal, a clock input for receiving a clock signal, a first output port for outputting the state of the latch, and a second output for outputting the inverted state of the latch.

The DAC may be configured to generate a low or high voltage in dependence of an output of the gated latch or in dependence of an inverted output of the gated latch. Furthermore, the DAC may comprise a voltage generation unit that comprises a first voltage unit for generating a low voltage, a second voltage unit for generating a high voltage, and a voltage switch for switching an output of the DAC between the first and second voltage unit, wherein the voltage switch is controlled in dependence of the output of the gated latch or in dependence of the inverted output of the gated latch.

The low-pass filter may comprise an active low-pass filter. For example, the active low-pass filter may comprise an active inverting operational amplifier low-pass filter. Such filter may comprise an operational amplifier having an inverting input, a non-inverting input, and an output, a resistive element arranged in between an output of the DAC and the inverting input, a capacitor arranged in between the inverting input and the output of the operational amplifier. The output of the operational amplifier may be connected to the second input of the comparator.

The initialization unit may comprise a reset switch that is connected in parallel to the capacitor.

Alternatively, the low-pass filter may comprise a passive low-pass filter. This filter may comprise a resistive element arranged in between an output of the low-pass filter and the DAC, and a capacitor arranged in between the output of the low-pass filter and ground, wherein the output of the low-pass filter is connected to the second input of the comparator. In this case, the initialization unit may comprise a reset switch arranged in between the first input of the comparator and the output node of the low-pass filter.

According to a second aspect, the present invention provides an electronic device that comprises the ADC as defined above. This device may comprise an X-ray detector having a pixel array and read-out circuitry for reading out pixel values of the pixels in the pixel array, wherein the ADC is arranged in the read-out circuitry and is configured to convert a read-out pixel value into a corresponding digital signal.

Next, the invention will be described in more detail by referring to the appended figures, wherein:

FIG. 1 illustrates a first known ADC;

FIG. 2 illustrates a second known ADC;

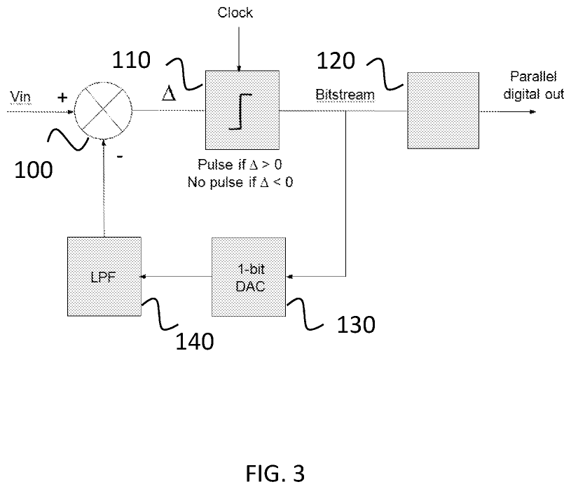

FIG. 3 illustrates a general topology of an ADC in accordance with the present invention;

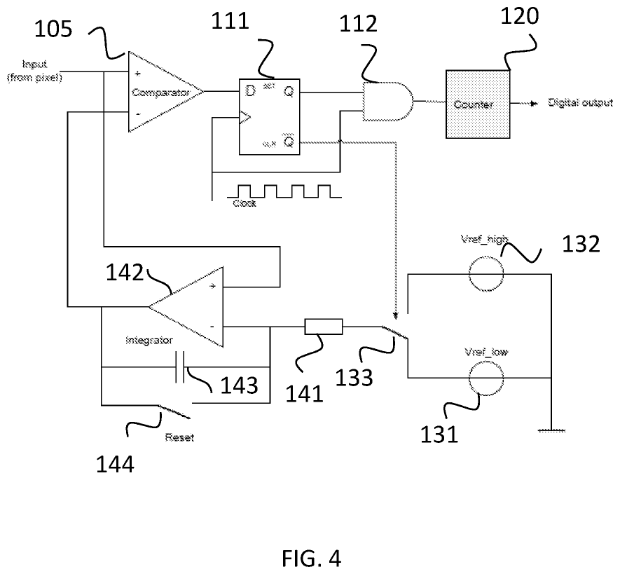

FIG. 4 illustrates a first implementation of the general topology depicted in FIG. 3;

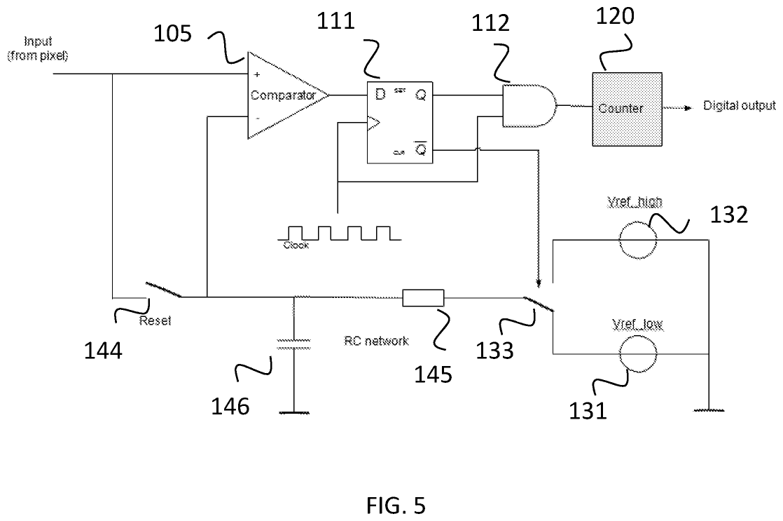

FIG. 5 illustrates a second implementation of the general topology depicted in FIG. 3; and

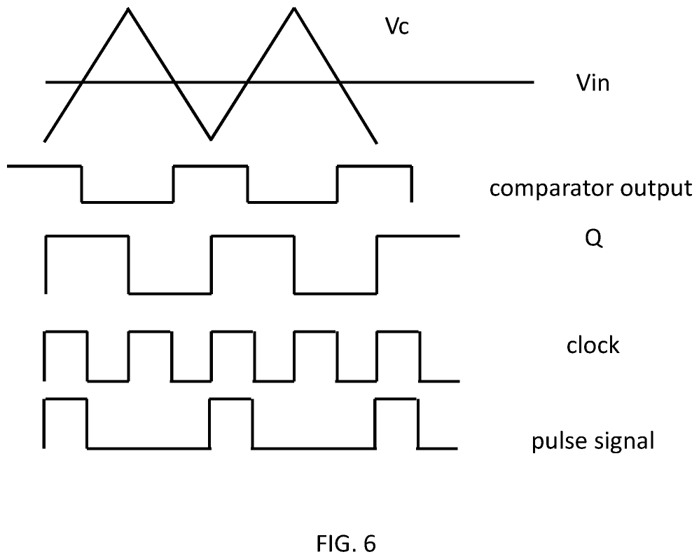

FIG. 6 illustrates the various signals in the topology of FIG. 5.

FIG. 3 illustrates a general topology of an ADC in accordance with the present invention. It comprises a subtractor 100 for subtracting a feedback signal from low-pass filter 140 from an input signal Vin. Substractor 100 feeds a difference signal to a pulse generating block 110 that compares the difference signal to a threshold, and, when the threshold is exceeded, generates a pulse in dependence of a clock signal. The output of pulse generating block 110 is connected to a counter 120 and to a one-bit DAC 130. The latter is connected to low-pass filter 140.

During operation, when the magnitude of the input signal is increased, more pulses will be generated by pulse generating block 110. Consequently, the low-frequency component of the signal outputted by DAC 130 will increase. This will in turn reduce the average difference signal outputted by subtractor 100 and less pulses will be generated by pulse generating block 110 until a balanced situation is achieved.

A first practical implementation of the topology in FIG. 3 is depicted in FIG. 4. Here, part of the functionality of subtractor 100 and pulse generating block 110 is realized by comparator 105. This latter block compares the input signal, received at its non-inverting input, to the feedback signal from operational amplifier 142, received at its inverting input, and outputs a high value if the input signal is larger than the feedback signal and a low value when it is smaller. This comparison signal is fed to a triggered pulse generator formed by a gated D latch 111 that has its non-inverting output connected to an AND gate 112. The other input of AND gate 112 receives a clock signal. This same signal is also fed to gated D latch 111.

DAC 130 from FIG. 3 is formed by a first voltage source 131 outputting a lower voltage and second voltage source 132 outputting a higher voltage. In addition, a switch 133 is used for switching between sources 131, 132 in dependence of the outputted inverted state of gated D latch 111.

FIG. 4 illustrates the implementation of low-pass filter 140 of FIG. 3 by an active inverting operational amplifier low-pass filter. This filter comprises an operational amplifier 142 having an inverting input connected to switch 133 via a resistive element 141. The non-inverting input of operational amplifier 142 is connected to the non-inverting input of comparator 105. The low-pass filter further comprises a capacitor 143 arranged in between the inverting input of operational amplifier 142 and the output of operational amplifier 142. This latter output is connected to the inverting input of comparator 105. A reset switch 144 is arranged in parallel to capacitor 143. When operated, it forces the output of operational amplifier 142, and the inverting input thereof, to be equal to the input signal. In this manner, an initialization unit can be implemented that is able to considerably reduce the time that is required after applying the input signal before a reliable output can be obtained.

FIG. 5 illustrates the implementation of low-pass filter 140 of FIG. 3 by a passive RC filter comprising a resistor 145 and a capacitor 146 to ground. Here, the connection point of resistor 145 and capacitor 146 is connected to the inverting input of comparator 105. Furthermore, a reset switch 144 is arranged in between the inverting input and non-inverting input of comparator 105. When operated, it forces the voltages at the inputs of comparator 105 to be equal and it allows a quick charging of capacitor 146. This represents a further implementation of an initialization unit.

FIG. 6 illustrates the various signals in the topology of FIG. 5. Before a conversion starts, the low-pass filter is initialized to the input signal Vin, i.e. capacitor 146 is charged to Vin, and the same voltage is then applied to comparator 105. In this example, Vin is roughly equal to a voltage halfway between the voltages of the first and second voltage sources 131, 132.

At the starting point of the curves in FIG. 6, gated D latch 111 has a state Q corresponding to a high value and Vin is larger than Vc, the voltage over capacitor 146. This will result in a high level at the output of comparator. At this moment, second voltage source 132 is connected to capacitor 146, resulting in an increasing Vc. At a given moment, Vc will exceed Vin causing the comparator output to change to a low level. At a next rising edge of the clock signal, gated D latch 111 will change its state to a low value. Consequently, first voltage source 131 will be connected to capacitor 146, resulting in a decreasing Vc. At a given moment in time, Vc will drop below Vin causing a high level at the comparator output. At a next rising edge of the clock signal, gated D latch 111 will change its state to a high value. Consequently, second voltage source 132 will be connected to capacitor 146, resulting in an increasing Vc. In the meantime, the output of gated D latch 111 and the clock signal are fed to AND gate 112. This will produce the pulse signal as indicated. The pulses in this signal are counted by counter 120.

The process in FIG. 6 is performed for a predetermined amount of time. Thereafter, counter 120 will output a digital value, for example related to the number of pulses counted and the predetermined amount of time. The higher the input signal, the more pulses are generated and the higher the counted value. The comparison process of comparator 105 is repetitive and consequently a single input signal is sampled multiple times (over-sampling).

Although the invention has been described using detailed embodiments thereof, the skilled person readily understands that the present invention is not limited to these embodiments, but that various modifications are possible without deviating from the scope of the invention, which is described by the appended claims.

1. An analog-to-digital converter (ADC), comprising:
a comparator comprising a first input for receiving an input signal and a second input for receiving a feedback signal, the comparator being configured to output a comparison signal in dependence of a difference between the input signal and the feedback signal;
a triggered pulse generator configured for outputting a digital pulse signal, the pulse generator being configured to generate a pulse in said digital pulse signal in dependence of a clock signal when the comparison signal exceeds a first threshold;
a digital-to-analog converter (DAC) for converting the digital pulse signal into an analog signal; and
a low-pass filter for filtering the analog signal and for providing the filtered analog signal to the comparator as the feedback signal.

2. The ADC according to claim 1, further comprising an output unit configured for receiving the digital pulse signal and for outputting a digital signal in dependence of the received digital pulse signal.

3. The ADC according to claim 2, wherein the digital signal comprises a digital word or digital value representing the magnitude of the input signal.

4. The ADC according to claim 2, wherein the output unit comprises a counting unit for counting the number of pulses in the digital pulse signal during a predefined amount of time, and a digital signal generating unit for generating the digital signal in dependence of the counted number of pulses.

5. The ADC according to claim 1, further comprising a sample-and-hold circuit for sampling a value of a signal to be converted and for providing a signal, which has a value that corresponds to the sampled value, as the input signal to the comparator.

6. The ADC according to claim 1, comprising an initialization unit for setting the feedback signal to a predefined level.

7. The ADC according to claim 6, wherein the predefined level substantially equals the value of the input signal.

8. The ADC according to claim 5, wherein the sample-and-hold circuit comprises a sampling unit for sampling the value of the signal to be converted and a holding unit for holding the sampled value during a predefined amount of time, wherein the initialization unit is configured to set the feedback signal to said predefined level at the start of holding the sampled value by the holding unit.

9. The ADC according to claim 1, wherein the triggered pulse generator comprises a gated latch and a logical gate connected to said latch, wherein the logical gate is configured to output said pulse in dependence of an output of the gated latch and said clock signal.

10. The ADC according to claim 9, wherein the DAC is configured to generate a low or high voltage in dependence of an output of the gated latch or in dependence of an inverted output of the gated latch.

11. The ADC according to claim 10, wherein the DAC comprises a voltage generation unit that comprises a first voltage unit for generating a low voltage, a second voltage unit for generating a high voltage, and a voltage switch for switching an output of the DAC between the first and second voltage unit, said voltage switch being controlled in dependence of said output of the gated latch or in dependence of said inverted output of the gated latch.

12. The ADC according to claim 1, wherein the low-pass filter comprises an active low-pass filter.

13. The ADC according to claim 12, wherein the active low-pass filter comprises an active inverting operational amplifier low-pass filter.

14. The ADC according to claim 13, wherein the active low-pass filter comprises:
an operational amplifier having an inverting input, a non-inverting input, and an output;
a resistive element arranged in between an output of the DAC and the inverting input;
a capacitor arranged in between the inverting input and the output of the operational amplifier;
wherein the output of the operational amplifier is connected to the second input of the comparator.

15. The ADC according to claim 14, wherein the initialization unit comprises a reset switch connected in parallel to the capacitor.

16. The ADC according to claim 1, wherein the low-pass filter comprises a passive low-pass filter.

17. The ADC according to claim 16, wherein the low-pass filter comprises a resistive element arranged in between an output of the low-pass filter and the DAC, and a capacitor arranged in between the output of the low-pass filter and ground, wherein the output of the low-pass filter is connected to the second input of the comparator.

18. The ADC according to claim 17, wherein the initialization unit comprises a reset switch arranged in between the first input of the comparator and the output node of the low-pass filter.

19. An electronic device comprising an analog-to-digital converter (ADC), comprising:
a comparator comprising a first input for receiving an input signal and a second input for receiving a feedback signal, the comparator being configured to output a comparison signal in dependence of a difference between the input signal and the feedback signal;
a triggered pulse generator configured for outputting a digital pulse signal, the pulse generator being configured to generate a pulse in said digital pulse signal in dependence of a dock signal when the comparison signal exceeds a first threshold;
a digital-to-analog converter (DAC) for converting the digital pulse signal into an analog signal: and
a low-pass filter for filtering the analog signal and for providing the filtered analog signal to the comparator as the feedback signal,

20. The electronic device according to claim 19, comprising an X-ray detector having a pixel array and read-out circuitry for reading out pixel values of the pixels in the pixel array, wherein the ADC is arranged in the read-out circuitry and is configured to convert a read-out pixel value into a corresponding digital signal.

21. The ADC according to claim 3, wherein the output unit comprises a counting unit for counting the number of pulses in the digital pulse signal during a predefined amount of time, and a digital signal generating unit for generating the digital signal in dependence of the counted number of pulses.

22. The ADC according to claim 6, wherein the sample-and-hold circuit comprises a sampling unit for sampling the value of the signal to be converted and a holding unit for holding the sampled value during a predefined amount of time, wherein the initialization unit is configured to set the feedback signal to said predefined level at the start of holding the sampled value by the holding unit.

23. The ADC according to claim 6, wherein the initialization unit comprises a reset switch connected in parallel to the capacitor.

24. The ADC according to claim 6, wherein the initialization unit comprises a reset switch arranged in between the first input of the comparator and the output node of the low-pass filter.
